(19) United States
(12) Patent Application Publication
(10) Pub. No.: US 2026/0343773 A1
(43) Pub. Date: Oct. 29, 2026

(54) ELECTRICAL DEVICE

(71) Applicant: Mitsubishi Electric Corporation, Tokyo (JP)

(72) Inventors: Hironobu HIGUCHI, Chiyoda-ku, Tokyo (JP); Keita NAKANO, Chiyoda-ku, Tokyo (JP)

(73) Assignee: Mitsubishi Electric Corporation, Tokyo (JP)

(21) Appl. No.: 19/491,184

(22) PCT Filed: Jun. 30, 2023
(86) PCT No.: PCT/JP2023/024431

§ 371 Date: Dec. 8, 2025

(51) Int. Cl. H05K 7/14; H02M 3/00; H02M 7/00; H05K 7/20

(52) U.S. Cl. CPC H05K 7/1432; H05K 7/20909; H02M 3/003; H02M 7/003

(57) ABSTRACT

An outdoor unit casing of an air conditioning outdoor unit houses an electronic substrate unit which supplies power to a compressor and in which a power conversion circuit is formed. The electronic substrate unit includes a substrate main body and a metal plate. The electronic substrate unit is disposed to face the outdoor unit casing with a space therebetween. The metal plate in the electronic substrate unit and the outdoor unit casing are electrically connected via a connection body. In the electronic substrate unit, a first connected portion is formed, to which one end of the connection body is connected. In the outdoor unit casing, a second connected portion is formed, to which the other end of the connection body is connected.

### TECHNICAL FIELD

The present disclosure relates to an electrical device.

### BACKGROUND ART

Electrical devices include an electrical device including a power conversion circuit. One of such electrical devices is an air conditioning outdoor unit used for an air conditioning apparatus. An outdoor unit casing of the air conditioning outdoor unit houses a compressor, an electronic substrate unit, a terminal block, a fan, and the like. In the electronic substrate unit, a power conversion circuit such as an inverter circuit is formed. Power supplied from an external power source to the electronic substrate unit via the terminal block is converted into desired power by the power conversion circuit, and thereafter is supplied to the compressor and the like.

The power conversion circuit such as the inverter circuit formed in the electronic substrate unit is a source of generating electromagnetic noise. The generated electromagnetic noise propagates to the external power source. Propagation paths through which the electromagnetic noise propagates include a propagation path through which the electromagnetic noise propagates via a wire connected to the electronic substrate unit, and a propagation path through which the electromagnetic noise propagates via the outdoor unit casing set to a ground potential. PTL 1 proposes a technique of suppressing electromagnetic noise that propagates via an outdoor unit casing.

### CITATION LIST

### Patent Literature

PTL 1: Japanese Patent Laying-Open No. 2015-117906

### SUMMARY OF INVENTION

### Technical Problem

PTL 1 proposes a technique of grounding a terminal block attached to the outdoor unit casing, to the outdoor unit casing, via a wire connected to the terminal block. The wire is likely to be influenced by an external electromagnetic field. An air conditioning outdoor unit is required to be less likely to be influenced by an external electromagnetic field.

The present disclosure has been made as a part of such development, and an object thereof is to provide an electrical device including a power conversion circuit that is less likely to be influenced by an external electromagnetic field.

### Solution to Problem

An electrical device according to the present disclosure is an electrical device including a power conversion circuit, the electrical device including a conductive casing, an electronic substrate unit, and a connection body. The electronic substrate unit is housed in the conductive casing, and includes the power conversion circuit and a noise filter. The connection body has a first end and a second end, and electrically connects the electronic substrate unit and the conductive casing. The electronic substrate unit includes a substrate main body and a conductor plate. The conductor plate is arranged on the substrate main body, and is electrically connected to the conductive casing. In the electronic substrate unit, a first connected portion is formed, to which the first end of the connection body is connected. In the conductive casing, a second connected portion is formed, to which the second end of the connection body is connected. The electronic substrate unit is disposed to face the conductive casing, with a space keeping member being interposed between the electronic substrate unit and the conductive casing. The first end of the connection body is electrically connected to the conductor plate in a state in which the first end is connected to the first connected portion, and the second end of the connection body is electrically connected to the conductive casing in a state in which the second end is connected to the second connected portion.

### Advantageous Effects of Invention

In the electrical device according to the present disclosure, the conductor plate arranged on the electronic substrate unit is electrically connected to the conductive casing via the connection body. The connection body is disposed between the electronic substrate unit and the conductive casing in a state in which the electronic substrate unit is located as close as possible to the conductive casing with the space keeping member being interposed between the electronic substrate unit and the conductive casing. Thereby, it is possible to reduce the length of the connection body which is considered to be likely to be influenced by external electromagnetic waves.

As a result, it is possible to suppress the electrical device from being influenced by an external electromagnetic field.

### BRIEF DESCRIPTION OF DRAWINGS

FIG. 1 is a perspective view schematically showing a structure of an air conditioning outdoor unit as an electrical device according to each embodiment.

FIG. 2 is a partial perspective view conceptually showing a structure for electrically connecting a metal plate arranged on an electronic substrate unit and an outdoor unit casing in each embodiment.

FIG. 3 is a partially exploded perspective view showing a connection part on an electronic substrate unit side in an air conditioning outdoor unit as an electrical device according to a first embodiment.

FIG. 4 is a partially exploded perspective view showing a connection part on an outdoor unit casing side in the same embodiment.

FIG. 5 is a partial side view including a cross section taken along a cross sectional line V-V shown in FIG. 2 in the same embodiment.

FIG. 6 is a partially exploded perspective view showing a structure for electrically connecting a metal plate arranged on an electronic substrate unit and an outdoor unit casing in an air conditioning outdoor unit as an electrical device according to a second embodiment.

FIG. 7 is a partial cross sectional view taken along a cross sectional line VII-VII shown in FIG. 6 in the same embodiment.

FIG. 8 is a partially exploded perspective view showing a structure for electrically connecting a metal plate arranged on an electronic substrate unit and an outdoor unit casing in an air conditioning outdoor unit as an electrical device according to a third embodiment.

FIG. 9 is a partial cross sectional view taken along a cross sectional line IX-IX shown in FIG. 8 in the same embodiment.

FIG. 10 is a partially exploded perspective view showing a structure for electrically connecting a metal plate arranged on an electronic substrate unit and an outdoor unit casing in an air conditioning outdoor unit as an electrical device according to a fourth embodiment.

FIG. 11 is a partial cross sectional view taken along a cross sectional line XI-XI shown in FIG. 10 in the same embodiment.

FIG. 12 is a perspective view schematically showing a structure of a modification of the air conditioning outdoor unit as the electrical device according to each embodiment.

### DESCRIPTION OF EMBODIMENTS

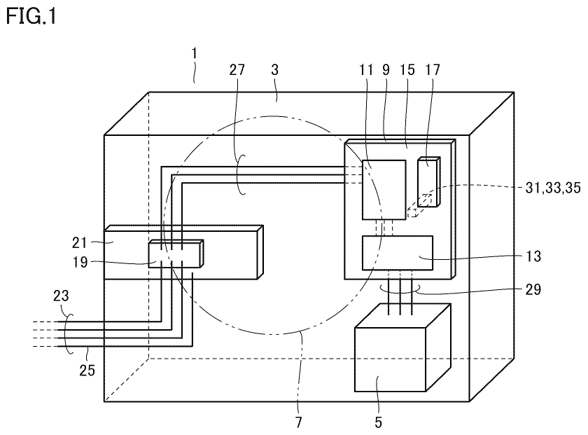

First, a description will be given of an example of an air conditioning outdoor unit used for an air conditioning apparatus, as an electrical device according to each embodiment. As shown in FIG. 1, in an air conditioning outdoor unit 1, an outdoor unit casing 3 as a conductive casing houses a compressor 5 for compressing refrigerant, an electronic substrate unit 9 and a terminal block 19 for supplying power to compressor 5 and the like, and a fan 7 and the like.

In electronic substrate unit 9, a power conversion circuit 13 such as an inverter circuit, a noise filter 11, and the like are formed. Terminal block 19 is disposed on a metal member 21. Metal member 21 is electrically connected to outdoor unit casing 3. A plurality of wires 23 electrically connected to an external power source (not shown) are connected to terminal block 19. Terminal block 19 and electronic substrate unit 9 are electrically connected by a plurality of wires 27. Electronic substrate unit 9 and compressor 5 are electrically connected by cables 29.

Power flows from the external power source through wires 23, terminal block 19, and wires 27, and is transmitted to electronic substrate unit 9. In electronic substrate unit 9, the transmitted power flows through noise filter 11 and power conversion circuit 13, and is converted into desired power. The converted power flows through cables 29, and is supplied to compressor 5 and the like. It should be noted that one wire 23 of wires 23 is electrically connected to metal member 21, as a grounding wire 25.

A disposition relation between electronic substrate unit 9 and outdoor unit casing 3 will be described in more detail. Electronic substrate unit 9 has a substrate main body 15. In substrate main body 15, power conversion circuit 13 and the like are formed. Electronic substrate unit 9 is disposed to face outdoor unit casing 3. Electronic substrate unit 9 and outdoor unit casing 3 are disposed with a space therebetween.

A plurality of metal plates for constituting an electrical circuit are arranged on substrate main body 15. FIG. 1 shows a metal plate 17 required to be electrically connected to outdoor unit casing 3, of the plurality of metal plates. Electromagnetic noise generated in power conversion circuit 13 propagates from metal plate 17 to outdoor unit casing 3. Metal plate 17 may be formed on any of main surfaces of substrate main body 15 opposite to each other. Further, when electronic substrate unit 9 has a plurality of stacked substrate main bodies 15, metal plate 17 may be disposed between stacked substrate main bodies 15.

FIG. 1 shows a state in which metal plate 17 is arranged on a main surface facing outdoor unit casing 3, of substrate main body 15, in order to more clearly show a disposition structure. In air conditioning outdoor unit 1, electronic substrate unit 9 and outdoor unit casing 3 are disposed to face each other with a minimum necessary space therebetween, with a space keeping member being interposed therebetween, in order to avoid an unexpected risk such as an electrical short circuit from a part other than metal plate 17 required to be electrically connected to outdoor unit casing 3.

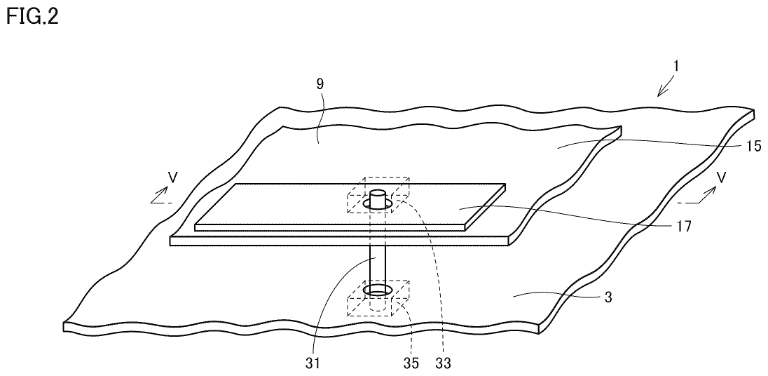

Next, a concept of a structure including a connection body 31 (see FIG. 2) that electrically connects electronic substrate unit 9 and outdoor unit casing 3 will be described. As shown in FIG. 2, metal plate 17 and outdoor unit casing 3 are electrically connected via connection body 31. Connection body 31 has one end and the other end. In metal plate 17 (electronic substrate unit 9), a first connected portion 33 is formed, to which the one end of connection body 31 is connected. In outdoor unit casing 3, a second connected portion 35 is formed, to which the other end of connection body 31 is connected.

It should be noted that FIG. 2 shows, as an exploded view, a state in which metal plate 17 is arranged on a main surface opposite to the main surface facing outdoor unit casing 3, of substrate main body 15, in order to more clearly show a disposition structure including connection body 31 and metal plate 17. Hereinafter, a structure including connection body 31 will be specifically described.

### First Embodiment

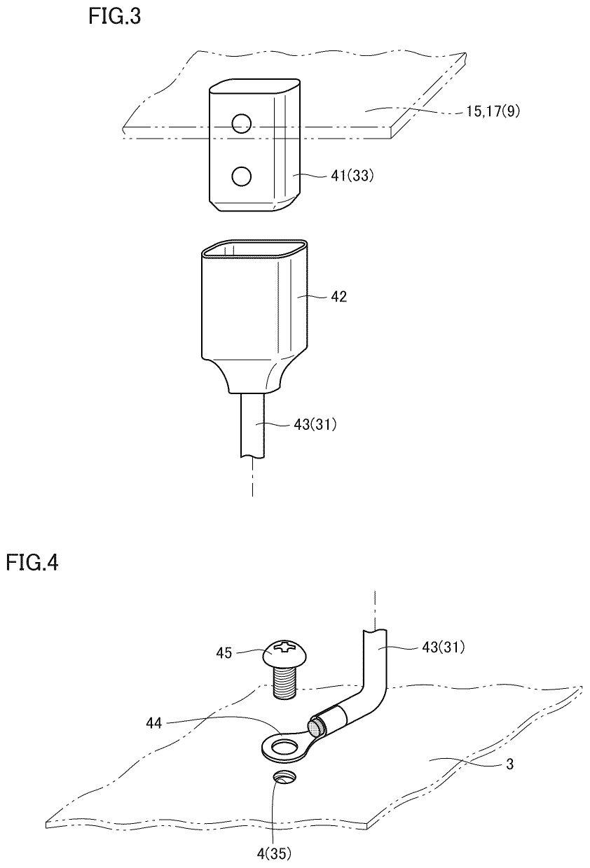

A description will be given of an example of an air conditioning outdoor unit used for an air conditioning apparatus, as an electrical device according to a first embodiment. Here, a wire member 43 is used as connection body 31. A structure including wire member 43 will be specifically described. As shown in FIG. 3, a female connector 42 is connected to one end of wire member 43. A male connector 41 as first connected portion 33 is attached to electronic substrate unit 9. Male connector 41 is electrically connected to metal plate 17. Female connector 42 is connected to male connector 41.

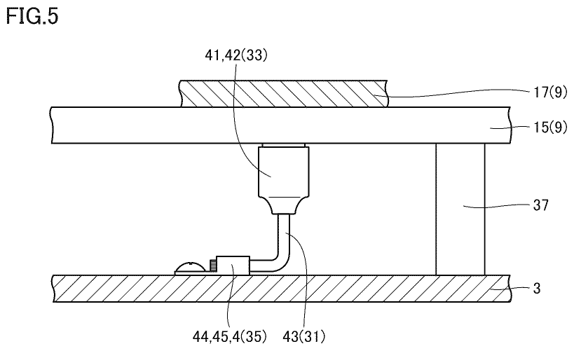

As shown in FIG. 4, a crimp terminal 44 is connected to the other end of wire member 43. A screw hole 4 as the second connected portion is formed in outdoor unit casing 3. A screw 45 is inserted through crimp terminal 44. Crimp terminal 44 is fixed to outdoor unit casing 3 by screwing screw 45 into screw hole 4.

FIG. 5 shows a state in which metal plate 17 and outdoor unit casing 3 are electrically connected by wire member 43. As shown in FIG. 5, in this case, a space keeping member 37 is disposed between electronic substrate unit 9 and outdoor unit casing 3, in order to maintain a state in which electronic substrate unit 9 is located as close as possible to outdoor unit casing 3.

In air conditioning outdoor unit 1 as the electrical device described above, metal plate 17 arranged on electronic substrate unit 9 is electrically connected to outdoor unit casing 3 via wire member 43. Wire member 43 is disposed between electronic substrate unit 9 and outdoor unit casing 3, in the state in which electronic substrate unit 9 is located as close as possible to outdoor unit casing 3. Thereby, it is possible to set the length of wire member 43 which is considered to be likely to be influenced by an external electromagnetic field, to the shortest length. As a result, it is possible to suppress air conditioning outdoor unit 1 from being influenced by the external electromagnetic field.

It should be noted that, although FIG. 5 and the like show one wire member 43 as wire member 43 that electrically connects metal plate 17 (electronic substrate unit 9) and outdoor unit casing 3, a plurality of wire members 43 may be provided. From the viewpoint of suppressing influence of the external electromagnetic field, it is considered to be desirable to provide one wire member 43. Further, wire member 43 is desirably thick and short.

Although the case of fixing the other end of wire member 43 to outdoor unit casing 3 by crimp terminal 44 and screw 45 has been described, the technique of fixing the other end of wire member 43 to outdoor unit casing 3 is not limited thereto. For example, a dedicated terminal may be applied instead of crimp terminal 44 and screw 45.

Further, although the case of electrically connecting the one end of wire member 43 to metal plate 17 by female connector 42 and male connector 41 has been described, the technique of electrically connecting the one end of wire member 43 to metal plate 17 is not limited thereto. For example, a through hole that penetrates substrate main body 15 including metal plate 17 may be provided, a wire member slightly thicker than the opening diameter of the through hole may be used as wire member 43, and one end of the wire member may be inserted into the through hole.

Furthermore, as connection body 31, for example, a plate-like conductive member may be applied, instead of wire member 43. In this case, first connected portion 33 corresponding to the plate-like conductive member is formed in electronic substrate unit 9, and second connected portion 35 corresponding to the plate-like conductive member is formed in outdoor unit casing 3.

### Second Embodiment

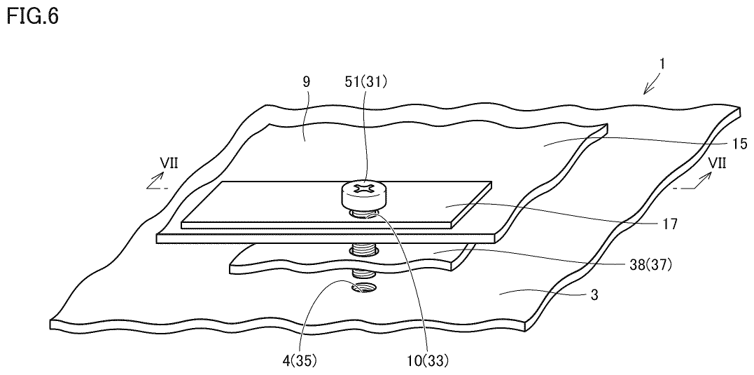

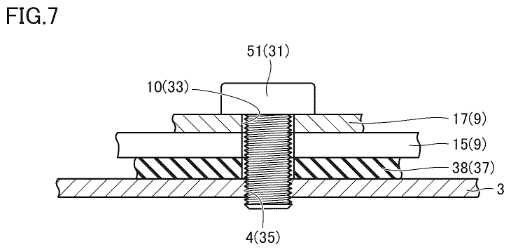

A description will be given of an example of air conditioning outdoor unit 1 as an electrical device according to a second embodiment. As shown in FIGS. 6 and 7, a screw 51 (male screw) is applied as connection body 31 that electrically connects metal plate 17 and outdoor unit casing 3. It should be noted that FIG. 6 shows an exploded view, in order to more clearly show a structure.

In substrate main body 15 including metal plate 17, an opening 10 as first connected portion 33 is formed, through which screw 51 is inserted. In outdoor unit casing 3, screw hole 4 is formed, into which screw 51 is screwed. The size of screw hole 4 is, for example, up to about M8. A sheet-like insulating material 38 is interposed between electronic substrate unit 9 and outdoor unit casing 3. It should be noted that, since other components are the same as those of air conditioning outdoor unit 1 shown in FIGS. 1 and 2, identical members will be designated by the same reference numerals, and the description thereof will not be repeated unless necessary.

As shown in FIG. 6, metal plate 17 is electrically connected to outdoor unit casing 3 by inserting screw 51 through opening 10 formed in electronic substrate unit 9 and a through hole formed in insulating material 38, and screwing screw 51 into screw hole 4 formed in outdoor unit casing 3. Further, electronic substrate unit 9 is firmly fixed to outdoor unit casing 3 by screw 51.

As shown in FIG. 7, a space corresponding to the thickness of sheet-like insulating material 38 is kept between electronic substrate unit 9 and outdoor unit casing 3. The thickness of insulating material 38 is set to a thickness that avoids an unexpected risk, such as an electrical short circuit from a part other than metal plate 17, between electronic substrate unit 9 and outdoor unit casing 3.

In air conditioning outdoor unit 1 as the electrical device described above, metal plate 17 arranged on electronic substrate unit 9 is electrically connected to outdoor unit casing 3 via screw 51. It is only necessary to set the length of screw 51 to a length that allows screw 51 to be screwed into screw hole 4 in outdoor unit casing 3 from electronic substrate unit 9 (opening 10).

Sheet-like insulating material 38 is interposed between electronic substrate unit 9 and outdoor unit casing 3. The space corresponding to the thickness of insulating material 38 is kept between electronic substrate unit 9 and outdoor unit casing 3.

Thereby, it is possible to significantly reduce the length of screw 51 as connection body 31 which is considered to be likely to be influenced by an external electromagnetic field. As a result, it is possible to suppress air conditioning outdoor unit 1 from being influenced by the external electromagnetic field.

Further, electronic substrate unit 9 is fixed to outdoor unit casing 3 by screw 51 having a head portion larger than the size of screw hole 4. Thereby, it is possible to fix electronic substrate unit 9 to outdoor unit casing 3 without using an additional member. It should be noted that, although the case where the opening shape of opening 10 is a circle has been described as an example, the opening shape may be, for example, an ellipse, a rectangle, or the like.

### Third Embodiment

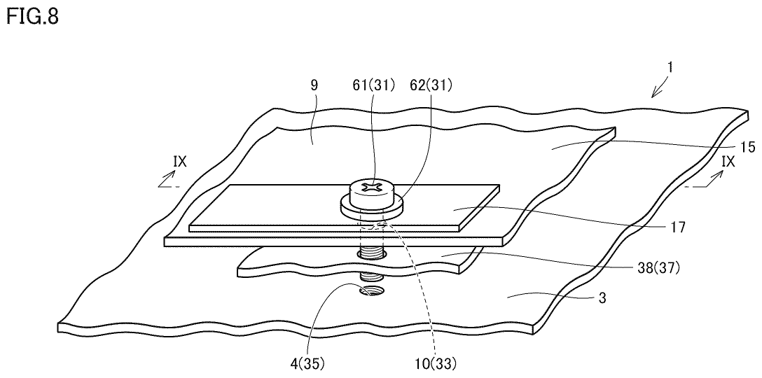

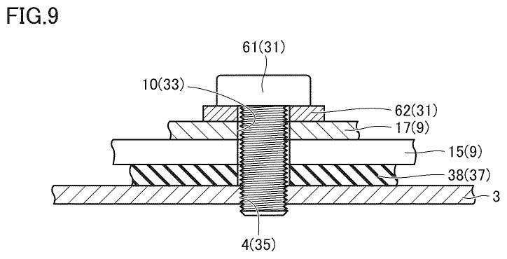

A description will be given of an example of air conditioning outdoor unit 1 as an electrical device according to a third embodiment. As shown in FIGS. 8 and 9, a screw 61 and an annular conductor portion 63 are applied as connection body 31 that electrically connects metal plate 17 and outdoor unit casing 3. The opening diameter of annular conductor portion 63 is larger than the diameter of screw 61. It should be noted that FIG. 8 shows an exploded view, in order to more clearly show a structure.

In substrate main body 15 including metal plate 17, opening 10 as first connected portion 33 is formed, through which screw 61 is inserted. In outdoor unit casing 3, screw hole 4 is formed, into which screw 61 is screwed. Sheet-like insulating material 38 is interposed between electronic substrate unit 9 and outdoor unit casing 3. It should be noted that, since other components are the same as those of air conditioning outdoor unit 1 shown in FIGS. 1 and 2, identical members will be designated by the same reference numerals, and the description thereof will not be repeated unless necessary.

As shown in FIG. 8, metal plate 17 is electrically connected to outdoor unit casing 3 by inserting screw 61 through opening 10 formed in electronic substrate unit 9 and the through hole formed in insulating material 38, with annular conductor portion 63 being interposed between a head portion of screw 61 and metal plate 17, and screwing screw 61 into screw hole 4 formed in outdoor unit casing 3.

In air conditioning outdoor unit 1 as the electrical device described above, metal plate 17 arranged on electronic substrate unit 9 is electrically connected to outdoor unit casing 3 via screw 61. As shown in FIG. 9, a space corresponding to the thickness of sheet-like insulating material 38 is kept between electronic substrate unit 9 and outdoor unit casing 3. Thereby, as described above, it is possible to significantly reduce the length of screw 61 as connection body 31 which is considered to be likely to be influenced by an external electromagnetic field. As a result, it is possible to suppress air conditioning outdoor unit 1 from being influenced by the external electromagnetic field.

Furthermore, in air conditioning outdoor unit 1, annular conductor portion 63 is interposed between the head portion of screw 61 and metal plate 17. Thereby, the conduction area between screw 61 and metal plate 17 substantially increases. As a result, it is possible to effectively ground metal plate 17 to outdoor unit casing 3 (a ground potential) via screw 61 and the like.

### Fourth Embodiment

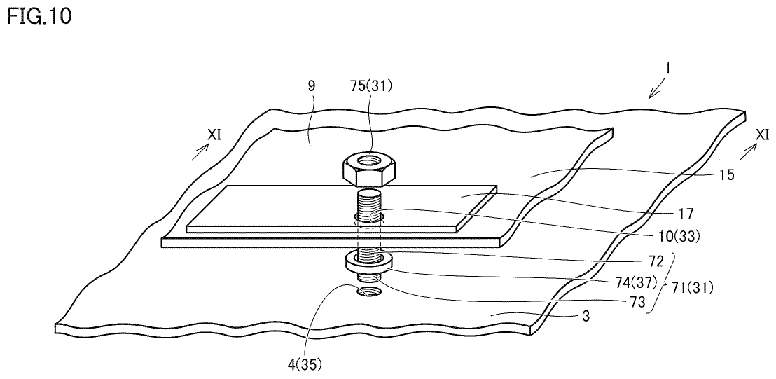

A description will be given of an example of air conditioning outdoor unit 1 as an electrical device according to a fourth embodiment. As shown in FIGS. 10 and 11, a spacer conductor jig 71 having a screw 72 formed at one end and a screw 73 formed at the other end, and a nut 75 screwed onto screw 72 are applied as connection body 31 that electrically connects metal plate 17 and outdoor unit casing 3. In spacer conductor jig 71, a collar portion 74 as a space keeping member is formed. The diameter of collar portion 74 is larger than the diameter of each of screws 72 and 73. It should be noted that FIG. 10 shows an exploded view, in order to more clearly show a structure.

In substrate main body 15 including metal plate 17, opening 10 as first connected portion 33 is formed, through which screw 72 is inserted. In outdoor unit casing 3, screw hole 4 is formed, into which screw 73 is screwed. Collar portion 74 is interposed between electronic substrate unit 9 and outdoor unit casing 3. It should be noted that, since other components are the same as those of air conditioning outdoor unit 1 shown in FIGS. 1 and 2, identical members will be designated by the same reference numerals, and the description thereof will not be repeated unless necessary.

As shown in FIG. 10, metal plate 17 is electrically connected to outdoor unit casing 3 via spacer conductor jig 71. In this case, screw 73 of spacer conductor jig 71 is screwed into screw hole 4 to bring collar portion 74 into contact with outdoor unit casing 3. In this state, screw 72 of spacer conductor jig 71 is inserted through opening 10 in electronic substrate unit 9. Nut 75 is screwed onto screw 72. Thereby, metal plate 17 is electrically connected to outdoor unit casing 3.

In air conditioning outdoor unit 1 as the electrical device described above, metal plate 17 arranged on electronic substrate unit 9 is electrically connected to outdoor unit casing 3 via spacer conductor jig 71. As shown in FIG. 11, a space corresponding to the thickness of collar portion 74 is kept between electronic substrate unit 9 and outdoor unit casing 3. The thickness of collar portion 74 is set to a thickness that avoids an unexpected risk, such as an electrical short circuit from a part other than metal plate 17, between electronic substrate unit 9 and outdoor unit casing 3.

Thereby, as described above, it is possible to significantly reduce the length of spacer conductor jig 71 as connection body 31 which is considered to be likely to be influenced by an external electromagnetic field. As a result, it is possible to suppress air conditioning outdoor unit 1 from being influenced by the external electromagnetic field.

It should be noted that, as connection body 31, spacer conductor jig 71 having screw 73 formed at the other end has been described as an example. As long as spacer conductor jig 71 has a structure that allows the other end thereof to be fastened to outdoor unit casing 3, spacer conductor jig 71 does not necessarily have to have screw 73 formed therein.

### Modification

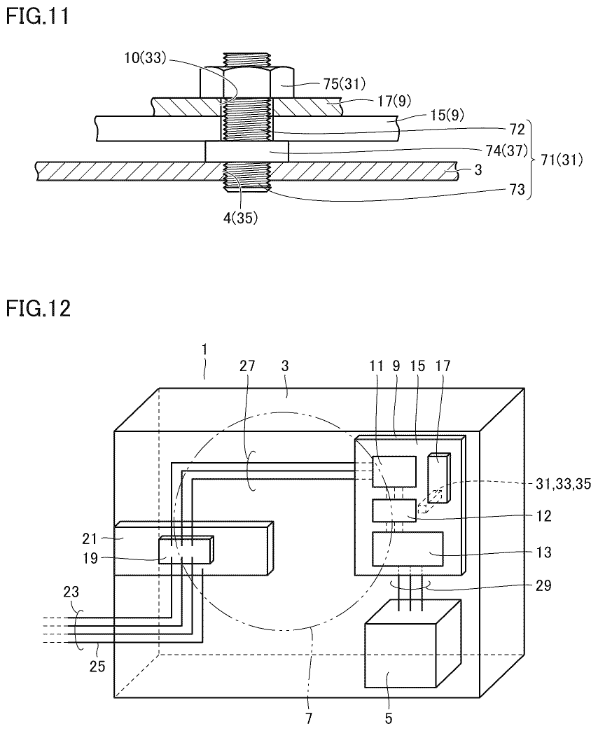

In air conditioning outdoor unit 1 according to each of the embodiments described above, electronic substrate unit 9 having noise filter 11 and power conversion circuit 13 formed therein has been described as an example. Electronic substrate unit 9 may be provided with a function of suppressing a surge caused by lightning. As shown in FIG. 12, in electronic substrate unit 9, a lightning protector 12 (a varistor or an arrester) is provided between noise filter 11 and power conversion circuit 13. Since other components are the same as those of air conditioning outdoor unit 1 shown in FIGS. 1 and 2, identical members will be designated by the same reference numerals, and the description thereof will not be repeated unless necessary.

In air conditioning outdoor unit 1 according to a modification, lightning protector 12 is provided in electronic substrate unit 9. Thereby, in the event of a lightning strike, it is possible to protect electronic substrate unit 9 housed in air conditioning outdoor unit 1 installed outdoors.

It should be noted that, in each of the embodiments described above, air conditioning outdoor unit 1 has been described as an example of the electrical device. The electrical device is not limited to air conditioning outdoor unit 1, and the present disclosure is applicable to an electrical device having a power converter such as an inverter circuit or a DC-DC converter circuit (Direct Current).

The air conditioning outdoor units described in the embodiments can be variously combined as necessary. For example, spacer conductor jig 71 described in the fourth embodiment may be applied instead of screw 61 described in the third embodiment.

The embodiments disclosed herein are illustrative and non-restrictive. The present disclosure is defined by the scope of the claims, rather than the scope described above, and is intended to include any modifications within the scope and meaning equivalent to the scope of the claims.

### INDUSTRIAL APPLICABILITY

The present disclosure is effectively utilized for an electrical device including a power conversion circuit.

### REFERENCE SIGNS LIST

1: air conditioning outdoor unit; 3: outdoor unit casing; 4: screw hole; 5: compressor; 7: fan; 9: electronic substrate unit; 10: opening; 11: noise filter; 12: lightning protector; 13: power conversion circuit; 15: substrate main body; 17: metal plate; 19: terminal block; 21: metal member; 23: electric wire; 25: grounding wire; 27: electric wire; 29: cable; 31: connection body; 33: first connected portion; 35: second connected portion; 37: space keeping member; 38: insulating material; 41: male connector; 42: female connector; 43: wire member; 44: crimp terminal; 45, 51, 61: screw; 62: annular conductive member; 71: spacer conductor jig; 72, 73: screw; 74: collar portion; 75: nut.

1. An electrical device including a power conversion circuit, the electrical device comprising:
a conductive casing;
an electronic substrate unit housed in the conductive casing, and including the power conversion circuit and a noise filter; and
a connection body having a first end and a second end, and electrically connecting the electronic substrate unit and the conductive casing, wherein
the electronic substrate unit includes
a substrate main body, and
a conductor plate arranged on the substrate main body, and electrically connected to the conductive casing,
in the electronic substrate unit, a first connected portion is formed, to which the first end of the connection body is connected,
in the conductive casing, a second connected portion is formed, to which the second end of the connection body is connected,
the electronic substrate unit is disposed to face the conductive casing, with a space keeping member being interposed between the electronic substrate unit and the conductive casing, and
the first end of the connection body is electrically connected to the conductor plate in a state in which the first end is connected to the first connected portion, and the second end of the connection body is electrically connected to the conductive casing in a state in which the second end is connected to the second connected portion.

2. The electrical device according to claim 1, wherein
the connection body includes a wire member having a female connector disposed at the first end and a crimp terminal disposed at the second end,
the first connected portion includes a male connector which engages with the female connector, and
the second connected portion includes a first screw hole into which a first screw inserted through the crimp terminal is screwed.

3. The electrical device according to claim 1, wherein
the connection body includes a second screw,
the first connected portion includes a substrate opening through which the second screw is inserted, and
the second connected portion includes a second screw hole into which the second screw is screwed.

4. The electrical device according to claim 3, wherein
the conductor plate is disposed on a surface opposite to a surface facing the conductive casing, of the substrate main body, and
the connection body includes an annular conductive member through which the second screw is inserted and which contacts the conductor plate.

5. The electrical device according to claim 3, wherein a sheet-like insulating material as the space keeping member is interposed between the substrate main body and the conductive casing.

6. The electrical device according to claim 1, wherein
the connection body includes
a conductor jig having a third screw formed at the first end and a fourth fifth screw formed at the second end,
a collar portion as the space keeping member, disposed between the first end and the second end in the conductor jig, and
a nut screwed onto the third screw,
the first connected portion includes a substrate opening through which the third screw is inserted, and
the second connected portion includes a third screw hole into which the fourth screw is screwed.

7. The electrical device according to claim 1, comprising:
a terminal block housed in the conductive casing, and relaying wires for supplying power of an external power source to the electronic substrate unit; and
a conductive member electrically connected to the conductive casing, and having the terminal block disposed thereon, wherein
the wires include a grounding wire, and
the grounding wire is electrically connected to the conductive member.

8. The electrical device according to claim 1, wherein, in the electronic substrate unit, a lightning protector is provided between the noise filter and the power conversion circuit.

9. The electrical device according to claim 1, comprising:
a compressor housed in the conductive casing, and electrically connected to the power conversion circuit; and
a fan housed in the conductive casing.
